(19) United States
(12) Patent Application Publication
(10) Pub. No.: US 2005/0022101 A1
(43) Pub. Date: Jan. 27, 2005

(54) Fast iteration termination of Turbo decoding

(76) Inventors: Peter Malm, Lund (SE); John B. Anderson, Lund (SE)

Correspondence Address: BURNS, DOANE, SWECKER & MATHIS, L.L.P., P.O. Box 1404, Alexandria, VA, 22313-1404, US

(21) Appl. No.: 10/622,742

(22) Filed: Jul. 21, 2003

(51) Int. Cl. G06F 11/00; H03M 13/00

(52) U.S. Cl. 714/801

(57) ABSTRACT

Turbo encoded information that comprises first systematic bits, first parity bits, second systematic bits, and second parity bits is decoded by supplying the first systematic bits and the first parity bits to a first decoder; supplying the second systematic bits and the second parity bits to a second decoder; and operating the first and second decoders in parallel for a number, m, of half-iterations, wherein m≧1. For each of the m half-iterations, the first decoder utilizes soft information supplied as an output from the second decoder in a preceding half-iteration, and the second decoder utilizes soft information supplied as an output from the first decoder in the preceding half-iteration. An early iteration termination decision is made by, after one or more of the m half-iterations, deciding whether to stop operating the first and second decoders by comparing an output from the first decoder with an output from the second decoder.

### BACKGROUND

The invention relates to decoding arrangements in communication systems, more particularly to Turbo decoders, and even more particularly to fast termination of Turbo decoder iterations.

In communication systems, a signal that represents information is sent from a transmitter to a receiver via a channel. When it is expected that the channel will distort the signal (which is usually the case in radio communication systems), any of a number of techniques are employed to mitigate this effect. One category of such techniques involves encoding the information in such a way prior to transmission that, when the complementary decoding process is performed at the receiver, it will be possible to correct and/or detect errors in the received signal. Encoding typically involves generating one or more extra bits as a function of the input information bitstream. These extra bits can then be transmitted along with the original information bits and used in the decoding process to correct and/or detect errors in the received bits.

One encoding/decoding technique that is known in the art is called Turbo decoding. Turbo decoding arrangements and operation are described in many publications, of which C. Berrou and A. Glavieux, “Near Optimum Error Correcting Coding and Decoding: Turbo-codes,” IEEE Transactions on Communications, 44(10), October 1996 is one example. FIG. 1 is a block diagram of a communication system that employs a classic Turbo decoder arrangement. On the transmitter side, an information bitstream, X, is supplied to a first encoder 101 and also to an interleaver 103. The interleaver 103 shuffles the information bitstream, X, and supplies the shuffled bits to a second encoder 105. The first encoder 101 generates a first stream of systematic bits, s1, and a first stream of parity bits, p1. The systematic bits, s1, represent the original information supplied to the first encoder 101, whereas the parity bits, p1, represent the redundant information generated by the first encoder 101.

The second encoder 105 similarly generates a second stream of systematic bits, s2, and a second stream of parity bits, p2. The systematic bits, s2, represent the original shuffled information bits supplied to the second encoder 105, and the parity bits, p2, represent the redundant information generated by the second encoder 105.

The outputs from the first encoder 101 and the second encoder 105 are supplied to a multiplexer 107, which combines them into a single bitstream that is to be transmitted to the receiver. It will be recognized that, since the systematic bits s2 merely represent a shuffled version of the systematic bits s1, it is not really necessary to transmit the systematic bits s2 to the receiver. This is represented in the figure by the use of dashed lines and parentheses. In embodiments in which only s1, p1 and p2 are transmitted, the receiver side would include circuitry (not shown) for re-creating s2 by suitably shuffling the received version of s1. For the sake of simplicity, the figure is drawn as though s2 were transmitted along with the other parameters s1, p1 and p2.

At the front end of the receiver, the received parameters s1, p1, s2 and p2 are recovered from the channel in the form of soft values. These values are supplied from a demultiplexer 109 that also splits them up into their constituent parts and supplies these parts in pairs to a respective one of a first maximum a posteriori (MAP) decoder 111 and a second MAP decoder 113. The first MAP decoder 111 operates on the non-interleaved vector s1, p1, and the second MAP decoder 113 operates on the interleaved vector s2, p2.

Typically, the decoding process starts with one run of the first decoder 111, which generates extrinsic information as well as an output vector L1. In the terminology of Turbo decoders, this procedure is called one half iteration. The extrinsic information is in the form of soft values, or estimates of the original transmitted data symbols, whereas the output vector L1 consists of hard values (i.e., the decided upon values that are considered to represent the original transmitted data symbols).

In the Turbo decoder arrangement, the extrinsic information generated by the first decoder 111 as a result of its half iteration is shuffled by an interleaver 115, and the shuffled information is then supplied to the second decoder 113. The second decoder 113 is then permitted to operate. The extrinsic information supplied by the first decoder 111 via the interleaver 115 is taken into account when the second decoder 113 performs its half iteration, which in turn produces extrinsic information as well as an output vector that, after un-shuffling by the deinterleaver 119, is an output vector Lⁱ₂. Since the second decoder operates on interleaved data, its outputs are also interleaved. Thus, the extrinsic information generated by the second decoder 113 is supplied to a deinterleaver 117 so that it may be passed on to the first decoder 111 for use in a next half iteration.

One full run of the first decoder 111 followed by a full run of the second decoder 113 constitutes one Turbo decoder iteration. Note that the order of operation for a classic Turbo decoder is first one run of the first decoder 111 followed by one run of the second decoder 113. The output of the classic Turbo decoder is supplied only by the output vector Lⁱ₂, so two “independently” decoded soft value vectors are only available once per iteration.

In operation, some number of Turbo decoder iterations are performed until the output vector Lⁱ₂ is considered to have converged on a reliable result. The speed of operation of this decoding arrangement is therefore heavily dependent upon the number of iterations that are considered to be needed.

Turbo decoders are being designed into more and more systems. For example, the third generation partnership project, 3GPP, has recently finalized Release 5 (R5) of the WCDMA specification. One of the new features in R5 is called high-speed downlink shared channel, HS-DSCH, and it enables peak transmission rates above 10 Mbps in the downlink direction on a channel that is shared among the users in a cell.

The Turbo decoder in the user equipment (UE) thus has to handle high bit rates. In the previous releases of the WCDMA standard, Release 99 and Release 4, the peak bit rate is approximately 2 Mbps. A number of measures can be taken to enhance the Turbo decoder's peak rate in the UE. These include higher clock frequency, faster MAP calculation in the constituent decoders, and the use of multiple Turbo decoders in a common “decoder pool”. Unfortunately, using a higher clock frequency results in much higher power consumption, so this solution can be regarded only as a last resort. Continued reliance on finding faster MAP implementations is also limited because the possibility of further parallelizing calculations in the UE's processing unit will sooner or later be exhausted.

Commonly assigned U.S. Provisional Application No. 60/394,320, filed on Jul. 8, 2002 and entitled “Method for Iterative Decoder Scheduling”, which is hereby incorporated herein by reference in its entirety, describes the pooling of a number of Turbo decoders in a common resource. This enables some amount of decoding to take place in parallel. Achieving good results in such an arrangement depends heavily on the ability to interrupt the Turbo decoding process as soon as a block of data is believed to be error free, or at least as soon as it is believed that performing additional iterations is not likely to improve the result.

Note, however, that it is advantageous to interrupt the iterative decoding process as soon as possible even if the UE only features one Turbo decoder. For example, assume that the decoder always performs a fixed number of iterations regardless of how the decoding process proceeds. If such a decoder is capable of decoding at the rate of 1 Mbps with eight iterations, then its capability is doubled to 2 Mbps if, on average, the decoder can be interrupted after four iterations. When Turbo decoders are employed in systems that also utilize automatic retransmission request (ARQ) strategies, the number of iterations required to decode a retransmitted block may typically be in that range.

It is therefore of paramount importance to interrupt the iterative decoding process as soon as possible. The simplest way to do this may be to apply an error-detecting code and check repeatedly for errors, for example, after each decoder iteration or half-iteration. However, some systems may not be able to check for errors, for example the 3GPP WCDMA does not facilitate this fast iteration termination strategy. The standard does feature a cyclic redundancy check (CRC), but that CRC is practically unusable as an iteration interrupter for two reasons:
1) There is an upper limit on the number of bits that can be encoded into one encoded block. Today, this limit is 5114 bits while the maximum transport block size in HS-DSCH is close to 28,800 bits.
2) The CRC is calculated over a transport block (up to 28,800 bits in HS-DSCH), and if more than 5114 bits are supplied to the Turbo encoder, then the transport block is split into several smaller blocks that are separately Turbo encoded.

The block-splitting procedure in the transmitter is illustrated in FIG. 2. The medium access control layer (MAC) 201 supplies a transport block consisting of N bits to the CRC unit 203. The CRC unit 203 appends 24 bits to the transport block in order to facilitate error-detection in the receiver. Hence, the transport block size N supplied by the MAC is increased to N+24 at the output of the CRC unit 203. A code block segmentation unit (CBS) then splits the N+24 bits into M blocks each of K bits, where M and K are calculated as:

$$\begin{matrix}M = ⌈ \frac{N + 24}{5114} ⌉ \\ K = \frac{N + 24 + f}{M} ,\end{matrix}$$

where f are filler bits to allow M equally-sized blocks. Each of these blocks is then separately encoded in the Turbo encoder (TE) 207.

A UE implementation that uses the CRC to determine when the Turbo decoding process can be interrupted must therefore iterate all M encoded blocks a certain number of decoder iterations and then concatenate the blocks before the CRC can be tried. If the CRC check does not indicate that the received transport block is error-free, then all blocks belonging to this transport block must run through additional iterations before the CRC can be checked again. This process is both slow and expensive in terms of electrical power.

It would therefore be beneficial to be able to determine, without checking the CRC, when there is no further profit to be gained by iterating each block anymore. This is true regardless of whether early termination means that there is a high likelihood that the bits were successfully decoded, or whether it means that further iteration is unlikely to improve a flawed result. It should be remembered in this context that HS-DSCH features a Layer-1 hybrid ARQ scheme with fast retransmissions. This means that a retransmitted transport block is soft-combined in the receiver with the previously failed version of the block. As a result, the iteration count for the soft-combined block will most likely be heavily reduced, typically by a factor of 2 to 3.

To reiterate, each of the above-mentioned factors, namely a high downlink bit rate, a CRC being calculated over an entire transport block instead of over each encoded block, and the use of hybrid ARQ with soft combination, makes the use of a static iteration count a waste of both processing time and electrical power. This is especially true of the hybrid ARQ scheme on Layer-1, because its use results in strong variations in the number of required decoder iterations. Hence, to optimize the usage of the Turbo decoder resource, the decoding process should be aborted as soon as possible.

The subject of prematurely stopping the iterative decoding process has been studied before and is reported in the literature. For example, three different criteria for stopping a classic Turbo decoder are presented in R. Y. Shao, S. Lin and M. P. C. Fossorier, “Two simple stopping criteria for Turbo decoding”, IEEE Transactions on Communications, 47(8):1117-1120, August 1999. The first stopping criterion described in the article basically relies on the weighted sum of the difference between the extrinsic information from the first and second decoders, respectively. The second stopping criterion described in the article involves counting the number of sign changes in the extrinsic information between two iterations. The third stopping criterion described in the article also utilizes differences between iterations.

Each of these three criteria has one or more drawbacks. For example, they each require that stopping decisions be made only at whole iteration boundaries. It will be remembered here that Turbo decoders run in increments of half-iterations. It would therefore be desirable to make stopping decisions at half-iteration boundaries, in order to make stopping decisions as soon as possible.

Also, the requirements in several of the described criteria to use soft extrinsic information and the weighting of values requires extra processing power.

Other documents also describe early termination of classic Turbo decoder iterations. For example, US, 2002/0026618, A1 discloses a hybrid early-termination strategy and output selection procedure for iterative Turbo decoders. Frames between successively-run half iterations are compared. In particular, a closeness measure based on hard decisions is calculated after every half-iteration. If it is decided that decoded frames Di and Di-0.5 are sufficiently close, then the parity of the decoded frame Di is checked. If the frame passes the parity-check, then the decoded frame Di is output and the iteration process is terminated. In addition to requiring that half-iterations be performed in succession, as in the classic Turbo decoder arrangement, this early termination strategy suffers from reliance, in part, on the parity-check results. As mentioned earlier, in some applications such as R5 of the WCDMA standard, the CRC is not present in each block, and can therefore not be checked for the purpose of determining whether the decoding of any particular block should be terminated.

Early termination strategies for classic Turbo decoders are also described in EP 1,178,613 A1; U.S. Pat. No. 5,761,248 A; US 2002/0010894 A1, A. Matache et al., “Stopping Rules for Turbo Decoders”, The Telecommunications and Mission Operations Progress Report 42-142, Jet Propulsion Laboratory, California Institute of Technology, Pasadena, Calif. under contract of NASA, August 2000' and X. Wang, “Cutting Power in Turbo Coding Architectures” , CommsDesign, May 22, 2002. These strategies all require sequential performance of half-iterations as in the classic Turbo decoder arrangement.

It is desirable to resort to non-conventional Turbo decoder arrangements for the purpose of achieving even greater speed improvements. One possibility involves operating the two decoders simultaneous1y (i.e., in parallel) rather than in succession, one after the other. Such an arrangement is described, for example, in William J. Blackert III, “Implementation Issues of Turbo Trellis Coded Modulation,” MSc. Thesis, University of Virginia, May 1996 (pp 34-40). This document does not, however, describe early termination strategies that are suitable for use in a parallel arrangement, nor can one expect that early termination strategies designed for use in the classic Turbo decoder arrangement will be suitable in a non-conventional, parallel arrangement. The reason for this is that the extrinsic information from the constituent decoders after the first half-iteration is not the same as the extrinsic information that is generated when the two decoders are operated in sequence, as in the classic Turbo decoder arrangement. The two constituent decoders will, therefore, work with different input signals during the second iteration and also in all subsequent iterations. Because of these differences, the design and operation of parallel-operated Turbo decoder arrangements cannot rely on teachings developed in connection with classic Turbo decoder arrangements.

Therefore, it is desirable to provide early termination strategies that are suitable for use in parallel Turbo decoder arrangements.

### SUMMARY

It should be emphasized that the terms “comprises” and “comprising”, when used in this specification, are taken to specify the presence of stated features, integers, steps or components; but the use of these terms does not preclude the presence or addition of one or more other features, integers, steps, components or groups thereof.

In accordance with one aspect of the present invention, the foregoing and other objects are achieved in methods and apparatuses that decode Turbo encoded information. The Turbo encoded information comprises first systematic bits, first parity bits, second systematic bits, and second parity bits. The Turbo encoded information is decoded by supplying the first systematic bits and the first parity bits to a first decoder; supplying the second systematic bits and the second parity bits to a second decoder; and operating the first and second decoders in parallel for a number, m, of half-iterations, wherein m is greater than or equal to 1. For each of the m half-iterations, the first decoder utilizes soft information supplied as an output from the second decoder in a preceding half-iteration, and the second decoder utilizes soft information supplied as an output from the first decoder in the preceding half-iteration. An early iteration termination decision is made by, after one or more of the m half-iterations, deciding whether to stop operating the first and second decoders by comparing an output from the first decoder with an output from the second decoder.

In one aspect of the invention, comparing the output from the first decoder with the output from the second decoder comprises comparing a hard decision from the first decoder with a hard decision from the second decoder. For example, it may be decided to stop operating the first and second decoders if the hard decision from the first decoder is equal to the hard decision from the second decoder. Alternatively, it may be decided to stop operating the first and second decoders based on a comparison of a threshold value with the Hamming distance between the output from the first decoder and the output from the second decoder. In some of these embodiments, prior to deciding whether to stop operating the first and second decoders, the threshold value is set equal to a value based on an earlier-determined Hamming distance. In such embodiments, deciding whether to stop operating the first and second decoders based on a comparison of the Hamming distance with the threshold value comprises deciding to stop operating the first and second decoders if the Hamming distance is greater than the threshold value.

In another class of alternative embodiments, comparing the output from the first decoder with the output from the second decoder comprises comparing soft values from the first decoder with soft values from the second decoder. For example, comparing soft values from the first decoder with soft values from the second decoder can comprise determining a distance between soft values from first decoder and soft values from second decoder. It can then be decided to stop operating the first and second decoders based on a comparison of the distance with a threshold value.

In some of these embodiments, deciding to stop operating the first and second decoders comprises deciding to stop operating the first and second decoders if the distance is less than a predetermined threshold value.

In alternative ones of these embodiments, prior to deciding whether to stop operating the first and second decoders, the threshold value is set equal to a value based on an earlier-determined distance. Then, it is decided to stop operating the first and second decoders if the distance is greater than the threshold value.

### BRIEF DESCRIPTION OF THE DRAWINGS

The objects and advantages of the invention will be understood by reading the following detailed description in conjunction with the drawings in which:

FIG. 1 is a block diagram of a communication system that employs a classic Turbo decoder arrangement.

FIG. 2 is a flow diagram of the block-splitting procedure performed in the transmitter of a communication system operating in accordance with R5 of the WCDMA standard.

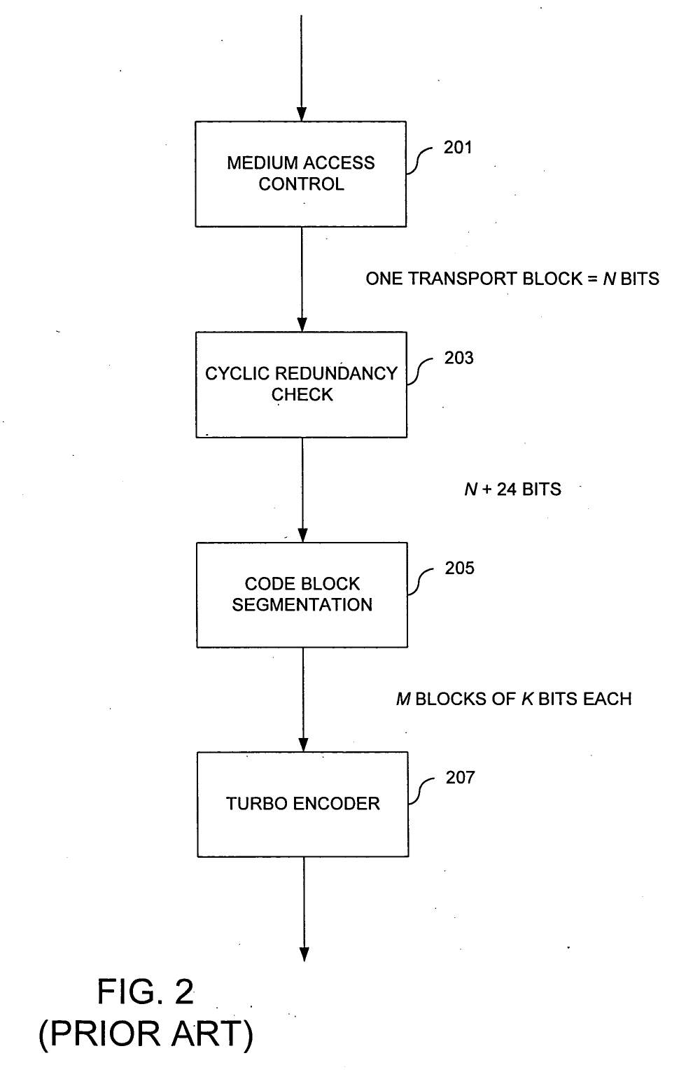

FIG. 3 is a block diagram of a transmitter-receiver chain in accordance with one aspect of the invention.

FIG. 4 presents test results in the form of a graph of BLER plotted as a function of E_{b}/N₀.

FIG. 5 presents test results in the form of a graph of iteration-count plotted as a function of E_{b}/N₀.

FIG. 6 is a flow diagram of an alternative Biturbo early termination strategy in accordance with one aspect of the invention.

FIG. 7 is a block diagram of a transmitter-receiver chain in accordance with an alternative embodiment of the invention in which a comparison unit is supplied with the soft outputs from first and second decoders.

### DETAILED DESCRIPTION

The various features of the invention will now be described with reference to the figures, in which like parts are identified with the same reference characters.

The various aspects of the invention will now be described in greater detail in connection with a number of exemplary embodiments. To facilitate an understanding of the invention, many aspects of the invention are described in terms of sequences of actions to be performed by elements of a computer system. It will be recognized that in each of the embodiments, the various actions could be performed by specialized circuits (e.g., discrete logic gates interconnected to perform a specialized function), by program instructions being executed by one or more processors, or by a combination of both. Moreover, the invention can additionally be considered to be embodied entirely within any form of computer readable carrier, such as solid-state memory, magnetic disk, optical disk or carrier wave (such as radio frequency, audio frequency or optical frequency carrier waves) containing an appropriate set of computer instructions that would cause a processor to carry out the techniques described herein. Thus, the various aspects of the invention may be embodied in many different forms, and all such forms are contemplated to be within the scope of the invention. For each of the various aspects of the invention, any such form of embodiments may be referred to herein as “logic configured to” perform a described action, or alternatively as “logic that” performs a described action.

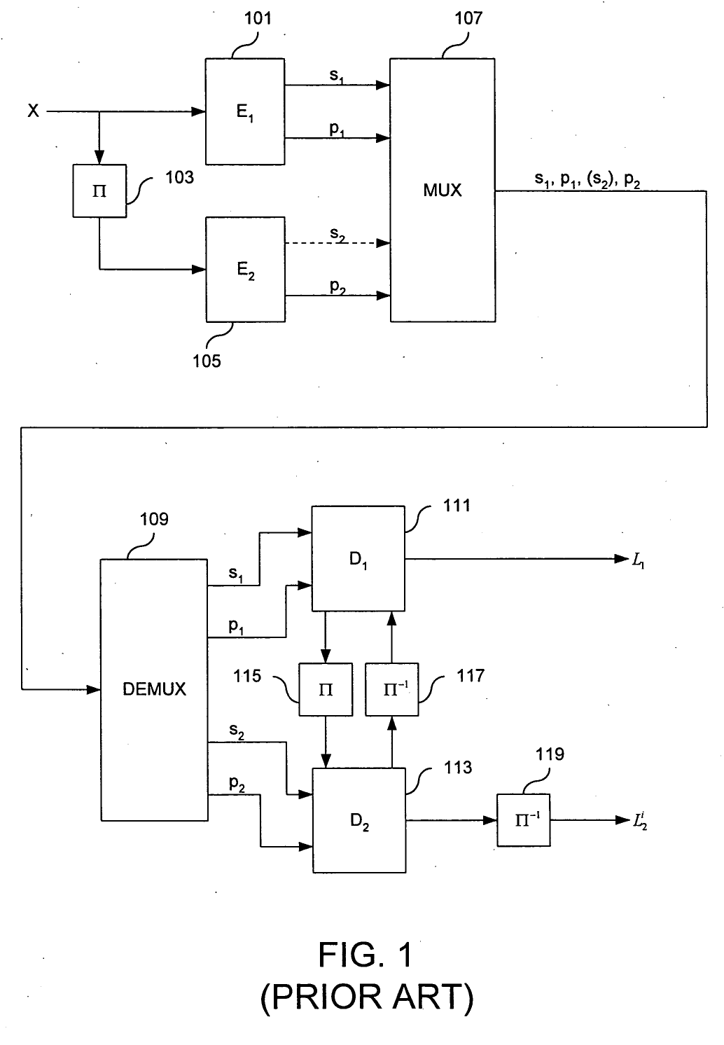

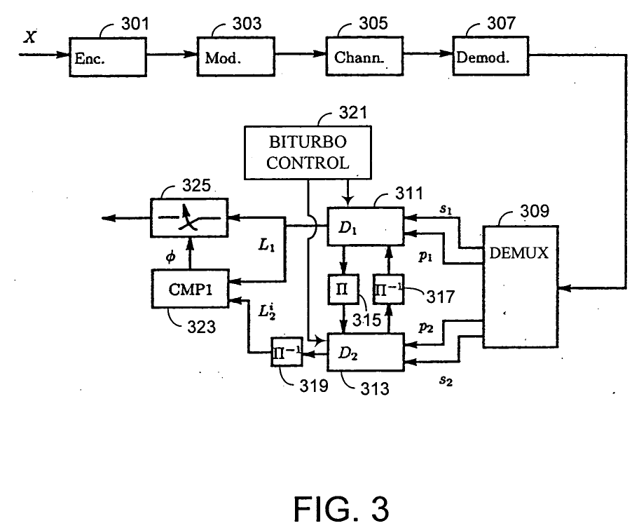

FIG. 3 is a block diagram of a transmitter-receiver chain in accordance with one aspect of the invention. On the transmitter side, information, X, is supplied to an encoder 301, which may for example comprise first and second encoders 101, 105; an interleaver 103 and a multiplexer 107 arranged as in FIG. 1. The encoded information supplied at the output of the encoder 301 is then modulated by a modulator 303 and transmitted over a channel 305.

In the receiver, the information supplied by the channel 305 is supplied to a demodulator 307, which generates soft values that need to be decoded. Considered individually, a number of the constituent parts of the decoder correspond to the constituent parts of a classic Turbo decoder. Thus, the decoder includes a demultiplexer 309 that splits the incoming stream of soft values into four vectors: two systematic vectors s₁ and s₂, and two parity vectors p₁ and p₂ as described in the BACKGROUND section. These four vectors are supplied to first and second decoders 311, 313 such that the first decoder 311 receives the vector pair s₁ and p₁, and the second decoder 313 receives the vector pair s₂, p₂. Extrinsic information is exchanged between the first decoder 311 and the second decoder 313 via an interleaver 315 and a de-interleaver 317, respectively. The output of the second decoder 313 is supplied to a second de-interleaver 319 so that the hard decisions supplied by the second decoder 313 will be suitably un-shuffled.

In accordance with one aspect of the invention, the first and second decoders 311, 313 are controlled by a Biturbo controller 321 in such a way that they are run in parallel. This means that the first decoder 311 and the second decoder 313 are made to run simultaneously and therefore produce results at the same time after each half-iteration. This method of operation is henceforth referred to as the Biturbo method. In this exemplary embodiment, early termination decisions are made based on hard-value vectors L₁ and Lⁱ₂. However, as will be described in greater detail in connection with alternative embodiments, it is also within the scope of the invention to use other metrics from the first and second decoders 311, 313, such as soft values instead of hard values.

The vectors L₁ and Lⁱ₂ are fed to a comparison unit 323 where they are bit-wise compared. If the hard values L₁ and Lⁱ₂ are found to be identical in the comparison unit 323, then the interactive decoding process is interrupted and either one of the hard decisions L₁ and Lⁱ₂ are fed to the next receiver blocks which, in WCDMA, are code block concatenation and then CRC decoding (neither are shown in FIG. 3). In FIG. 3, this is depicted as a switch 325 which allows the hard decision L1 to pass through to the output of the decoder only when instructed to do so by the output of the comparison unit 323. It will be recognized that, in this particular embodiment, it does not matter which of the hard decisions L₁ and Lⁱ₂ are used, since they only represent the final output of the decoder when they are equal to one another. It will further be recognized that the decision to terminate iterations at this point does not necessarily mean that the decoded block is error-free. It may mean this, or it may alternatively mean that the performance of additional iterations is unlikely to improve the result. It is left to the subsequent CRC decoding to determine whether a concatenated group of decoded blocks is error-free. If the CRC decoding determines that one or more errors are present, then in a communications system that employs an ARQ strategy, the blocks will be retransmitted. Upon reception and demodulation, the retransmitted blocks can be soft-combined with their earlier-received counterparts and again run through the Biturbo decoder process.

The bit-wise comparison in the comparison unit 323 can be performed once per half-iteration. This enables a fast iteration termination. For example, the time until the decoding process can be interrupted is decreased by 50% in the first iteration compared to a classic Turbo decoder structure, which produces output only once per iteration.

A test was conducted to prove the feasibility of the invention. Some of the test parameters were as follows:
Block length: 5000 bits.
Code rate in first transmission: 0.52.
Maximum iteration count: 8 iterations.
Type of modulation: 16 QAM in AWGN.

The arrangement depicted in FIG. 3 was tested. In the test, a user data vector X was encoded by a Turbo encoder 301, modulated by a modulator 303, transmitted over a channel 305, and demodulated by a demodulator 307, all according to the 3GPP WCDMA specifications set forth in “Technical specification group radio access network; multiplexing and channel coding (FDD) (release 5),” 3GPP TS 25.212 V5.2.0, 2002; and in “Technical specification group radio access network; spreading and modulation (FDD) (release 5),” 3GPP TS 25.213; V5.2.0, September 2002, both of which are hereby incorporated herein by reference in their entireties. Not shown in the figure is rate matching and its inverse (rate de-matching) which matches the encoded bit-vector to the physical channel's capability.

The demultiplexer 309 in FIG. 3 splits the demodulated soft values into four different vectors as described earlier. The four different soft value vectors s₁, p₁, s₂, and p₂ are then fed to respective ones of the first and second decoders 311, 313, which operate on non-interleaved and interleaved vectors, respectively. The hard decisions L₁ and Lⁱ₂ are fed to the comparator 323 after each half-iteration.

The comparator 323 compares the hard decisions L₁ to the hard decisions Lⁱ₂ and outputs the outcome of the comparison, φ, defined as

$$ϕ = {\sum }_{k} \vert {L}_{1 , k} - {L}_{2 , k}^{i} \vert ,$$

where L_{1,k} is L₁'s k:th component and Lⁱ_{2,k} is L¹₂'s k:th component. Consequently,

$$ϕ = \{ \begin{matrix}0 & if {L}_{1} and {L}_{2}^{i} are equal in all positions , \\ η & where η > 0 , if {L}_{1} and {L}_{2}^{i} are different in one or more positions .\end{matrix}$$

Four different modes of operation were tested: two employing different early-termination schemes, one always using a maximum iteration-count (in this case 8 iterations), and another using a hypothesized termination-genie scheme. The genie always terminates the iteration process as soon as the decoder has reached the correct data vector. That is, the genie always knows what the transmitted bit-vector X is. Hence, the genie represents the lower bound on the number of required decoder iterations for correct decoding.

The two early-termination strategies that were tested were:
the inventive Biturbo scheme, described above; and
a strategy that compares successive half-iterations in a classic Turbo decoder arrangement.

The strategy comparing successive half-iterations compares hard user data bit decisions between consecutive half-iterations, while the inventive Biturbo scheme, as explained above, compares parallel-decoded hard decisions. The reason for comparing Biturbo to the conventional strategy is two-fold: the conventional strategy is inherently simple to implement, and it gives surprisingly good performance, as described in the A. Matache et al. document referenced above in the BACKGROUND section.

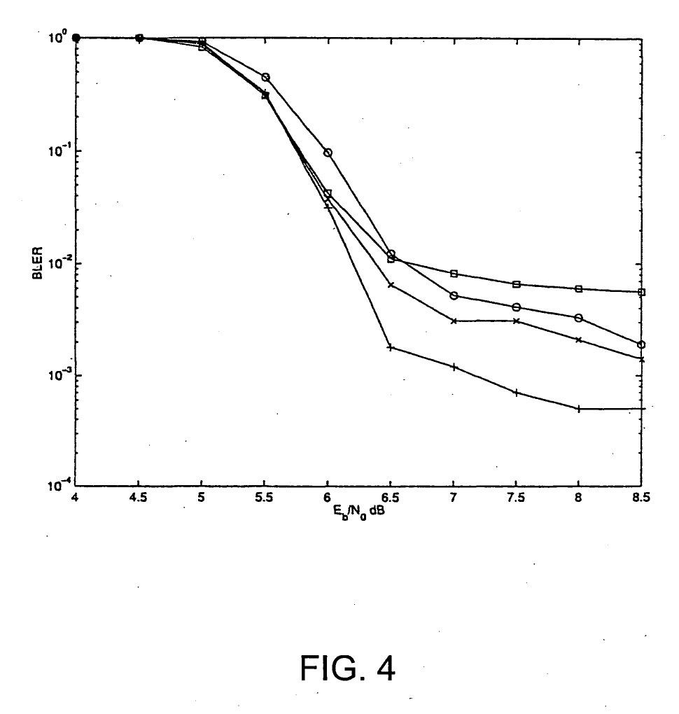

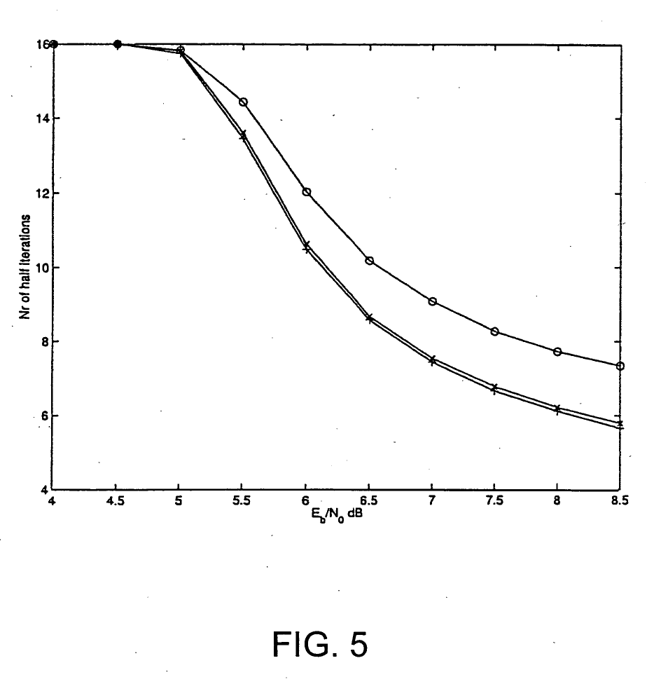

The results of the tests are depicted in FIGS. 4 and 5. More specifically, FIG. 4 is a graph of block error rate (BLER) plotted as a function of E_{b}/N₀ (the signal-to-noise ratio). The test results for the Biturbo strategy are indicated by “x”; the results for the “compare successive half-iteration” strategy are indicated by “∘”, the results for the maximum iteration-count strategy are indicated by “□”, and the results for the “genie” are indicated by “+”. The BLER operating range is 1% to 50%; that is, 5.5≦E_{b}/N₀≦6.5 dB.

FIG. 5 is a graph of the number of required half-iterations plotted as a function of E_{b}/N₀. The test results for the Biturbo strategy are indicated by “x”; the results for the “compare successive half-iteration” strategy are indicated by “∘”, and the results for the “genie” are indicated by “+”. It will be recalled that the maximum iteration-count strategy always used 8 whole iterations (=16 half-iterations), so this was not plotted in order to avoid cluttering the figure.

It should be seen from FIG. 4 that the penalty in E_{b}/N₀ for the Biturbo strategy compared to the genie is rather small in the operative area of HS-DSCH, that is, from 1% BLER and upwards. The Biturbo strategy actually needs less E_{b}/N₀. than the Classic Turbo decoder with Maximum iteration-count strategy. However, as can be seen in FIG. 5, the iteration count for the inventive Biturbo strategy is between 0.5-1.0 full iteration lower than the “compare successive half-iterations” method, and only s1ightly worse than the lower bound represented by the genie. Furthermore, the fact that in the Biturbo strategy the half-iterations of the two decoders are performed simultaneous1y means that the designer can gain a speed advantage, or can trade-off some or all of this speed improvement in exchange for using slower parts.

Some exemplary numbers will illustrate this point. If each user-data bit consumes 4 clock-cycles and the clock frequency is 30 MHz, then one full Turbo decoder iteration with block length 5000 user-data bits and the inventive Biturbo decoder corresponds to

$${T}_{iter} = \frac{4 \cdot 5000}{30 \cdot {10}^{6}} = 0.67 ms .$$

The total UE processing time in HS-DSCH is 5 ms. During this time, the following processing tasks need to be performed in the UE apart from Turbo decoding:
despreading and combining
soft-value generation
de-interleaving and de-segmentation
rate de-matching 1 and 2
combination with stored soft values
block concatenation in case there is more than one encoded block per transport block
CRC calculation
ACK/NACK report generation.
   If it is assumed that 3 ms of the total 5 ms UE processing time is assigned to Turbo decoding, then one full iteration corresponds to 22% of the available decoding time at a 30 MHz clock frequency.

This means that one could design equipment that employs the Biturbo arrangement (including the Biturbo early termination strategy), and run it at a lower Turbo decoder clock frequency than one would otherwise use for a classic Turbo decoder. For example, again assume a user-data size of 5000 bits, 4 clock cycles per user-data bit, and 3 ms available for decoding. From FIGS. 4 and 5, it can be seen that for 5% BLER, it is necessary to do 11 half-iterations with the Biturbo method, whereas the “compare successive half-iterations” method (run on a classic Turbo decoder) would require 13 half-iterations. This corresponds to the following clock frequencies:

$${f}_{clk} = \{ \begin{matrix}37 & MHz for the Biturbo strategy \\ 43 & MHz for {the }^{″} compare succesive half - {iterations}^{″} strategy\end{matrix}$$

The Biturbo method thus corresponds to a clock frequency that is 16% lower than the competing method. Note that clock frequencies as high as 50 MHz may be unfeasible in a real implementation. Therefore, in a practical embodiment using presently existing technology and the above exemplary operating parameters, additional measures may be necessary to allow a reasonable clock frequency. For example, one might equip the UE with additional Turbo decoders and use statistical multiplexing, which together with fast iteration termination, allows for maximal use of the decoders. This is further described in the U.S. Provisional Application No. 60/394,320, which was incorporated herein by reference above. Of course, in other applications that do not use the operating parameters hypothesized above, the Biturbo arrangement may be used alone, without any additional measures taken. In all cases, however, the performance of the Biturbo arrangement and early termination strategy is substantially better than that of the classic Turbo decoder operated with the conventional “compare successive half-iterations” strategy.

The exemplary embodiments of the Biturbo early-termination strategy described above are based on comparisons between hard decisions (i.e., the outputs L₁ and Lⁱ₂ of the first and second decoders 311, 313), and in particular these embodiments make a decision to terminate the decoding process when it is determined that L₁ and Lⁱ₂ are equal to one another. In an alternative embodiment, the comparison strategy may be modified to stop iterations when it is determined that the Hamming distance between L₁ and Lⁱ₂ (i.e., the integer that represents the number of bits in which the binary numbers L₁ and Lⁱ₂ disagree) is less than a threshold value. In another alternative embodiment, the comparison strategy may be modified to stop iterations when it is believed that the present output from the decoder is not likely correct, but that too many more iterations would be required to generate a correct result. Such a strategy is useful in systems that also employ an ARQ strategy because, in the long run, fewer total iterations may be required if the present decoding effort is terminated early in favor of decoding a subsequently retransmitted block that has been soft-combined with the earlier-received block. In this case, termination can be based on the Hamming distance between L₁ and Lⁱ₂ being greater than a particular threshold. In some embodiments, it may be useful to delay application of this termination test until a minimum number of initial iterations have been carried out, since there is likely to be a greater distance between L₁ and Lⁱ₂ after the first few iterations. The particular threshold used in these embodiments may be predefined, or dynamically determined. An exemplary embodiment of a dynamically determined threshold is the use of a number, Nₖ which represents the Hamming distance between L₁ and Lⁱ₂ after an iteration, k. A decision to stop would be made when the Hamming distance Nₖ₊₁>Nₖ, where k+1 is the next half-iteration after iteration k. The reason for stopping at this point is that the condition Nₖ₊₁>Nₖ suggests that the decoder may have reached an oscillating state.

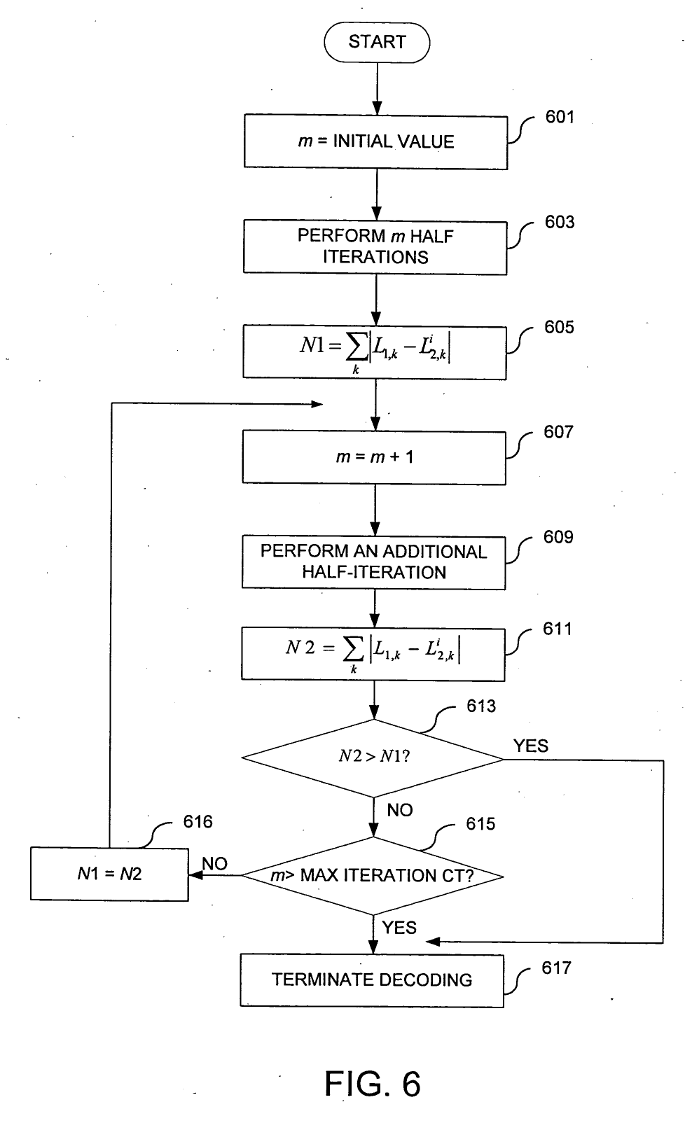

The just-described alternative Biturbo early termination strategy is illustrated in the flow chart of FIG. 6. In order to avoid prematurely terminating the Biturbo decoder operations, a half-iteration counter, m, is set to a predetermined initial value that is greater than or equal to zero (step 601). Then, the Biturbo decoder is permitted to perform m half-iterations without any early termination test being performed (step 603).

After the initial number of half-iterations have been performed, a variable N1 is set equal to the Hamming distance between L₁ and Lⁱ₂ (step 605). The Hamming distance for k-bit values may be defmed as

$$N1 = {\sum }_{k}^{} \vert {L}_{1 , k} - {L}_{2 , k}^{i} \vert .$$

Next, the half-iteration counter m is incremented (step 607), and the Biturbo decoder is operated for an additional half-iteration (step 609). A second variable, N2 is set equal to the Hamming distance between L₁ and Lⁱ₂ after this additional half-iteration (step 611).

The two variables N1 and N2 are then compared with one another (decision block 613). If N2 is less than or equal to N1 (“NO” path out of decision block 613), then a test is performed to determine whether a maximum number of half-iterations has been performed (decision block 615). If the maximum number of half-iterations has not yet been performed (“NO” path out of decision block 615), then N1 is set equal to the value of A2 (step 616). Processing then returns to step 607, and another half-iteration is performed, followed by another set of termination tests. Otherwise (“YES” path out of decision block 615), Biturbo decoder operation is terminated (step 617). In alternative embodiments, setting N1 equal to the value of N2 (step 616) may be omitted.

Returning to decision block 613, if N2 is found to be greater than N1 (“YES” path out of decision block 613), then a possible oscillating state is indicated and Biturbo decoder operation is terminated (step 617).

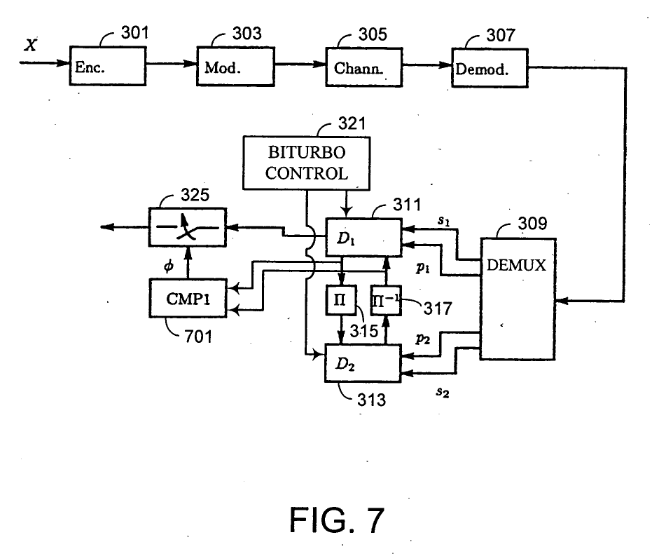

In still other alternative embodiments, early termination decisions can be based on soft outputs from the first and second decoders 311, 313 instead of on the hard decisions L₁ and Lⁱ₂. For example, FIG. 7 is a block diagram of a transmitter-receiver chain in accordance with an alternative embodiment of the invention in which a comparison unit 701 is supplied with the soft outputs from the first and second decoders 311, 313. In this case, the comparison unit 701 may operate by calculating the distance between the two soft-value vectors S₁ and Sⁱ₂ generated by the first and second decoders 311, 313, respectively. Here, S₁ and Sⁱ₂ are soft-value equivalents of L₁ and Lⁱ₂. The distance between S₁ and Sⁱ₂ can, for example, be defmed as:

$$δ = {\sum }_{k}^{} \vert {S}_{1 , k} - {S}_{2 , k}^{i} \vert ,$$

where S_{1,k} and Sⁱ_{2,k} are the k:th components of S₁ and Sⁱ₂, respectively. The distance δ can then be compared to a threshold γ₁. That is, if
δ<γ₁,
then the comparison unit 701 considers that the first and second decoders 311, 313 have produced vectors that are close enough that decoding should be terminated, and hard values should be calculated from either S₁ or Sⁱ₂. After the hard values are calculated (e.g., by the first decoder 311), the switch 325 is operated to supply the hard decision output from one of the selected one of the decoders (e.g., the output from the first decoder 311) as the output from the entire decoding process. These hard decision values are fed to the CRC check after concatenation with other decoded blocks that belong to the same transport block.

In still another aspect of the invention, the magnitude of the soft values from the first and second decoders 311, 313 can be used as the basis for assessing the reliability of the decision. Such a test could, for example, include the following comparison

$${γ}_{2} \begin{matrix}{<}^{OK} \\ {>}_{not OK}\end{matrix} min ( {\sum }_{k}^{} \vert {S}_{1 , k} \vert , {\sum }_{k}^{} \vert {S}_{2 , k}^{i} \vert )$$

where γ₂ is a suitable threshold. As shown by the equation, if the right side of the expression is greater than γ₂ then the receiver can consider that the outcome of the soft or hard comparison operation (e.g., the output of either of the exemplary comparison units 323 or 701) is reliable. A suitable value for γ₂ can be selected from experience with the equipment.

Both thresholds γ₁ and γ₂ can be subject to optimization; that is, fine-tuning of γ₁ and γ₂ leads to an optimized performance. The flexibility and fine-tuning possibilities that are achieved when both γ₁ and γ₂ are implemented speaks in favor of using both tests simultaneously.

The invention has been described with reference to a particular embodiment. However, it will be readily apparent to those skilled in the art that it is possible to embody the invention in specific forms other than those of the preferred embodiment described above. This may be done without departing from the spirit of the invention.

For example, the various embodiments described above have utilized either the L- or S-vectors generated by the first and second decoders 311, 313. However, metrics such as intermediate results in two MAP decoders, arranged in a Biturbo configuration, can be used instead of L- or S-vectors in order to speed up the fast iteration termination and to decrease the power consumption.

Thus, the preferred embodiments are merely illustrative and should not be considered restrictive in anyway. The scope of the invention is given by the appended claims, rather than the preceding description, and all variations and equivalents which fall within the range of the claims are intended to be embraced therein.

1. A method of decoding Turbo encoded information that comprises first systematic bits, first parity bits, second systematic bits, and second parity bits, the method comprising:
supplying the first systematic bits and the first parity bits to a first decoder;
supplying the second systematic bits and the second parity bits to a second decoder;
operating the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
after one or more of the m half-iterations, deciding whether to stop operating the first and second decoders by comparing an output from the first decoder with an output from the second decoder.

2. The method of claim 1, wherein comparing the output from the first decoder with the output from the second decoder comprises:
comparing a hard decision from the first decoder with a hard decision from the second decoder.

3. The method of claim 2, wherein deciding whether to stop operating the first and second decoders by comparing the output from the first decoder with the output from the second decoder comprises:
deciding to stop operating the first and second decoders if the hard decision from the first decoder is equal to the hard decision from the second decoder.

4. The method of claim 2, wherein deciding whether to stop operating the first and second decoders by comparing the output from the first decoder with the output from the second decoder comprises:
determining a Hamming distance between the output from the first decoder and the output from the second decoder; and
deciding whether to stop operating the first and second decoders based on a comparison of the Hamming distance with a threshold value.

5. The method of claim 4, wherein deciding whether to stop operating the first and second decoders comprises:
deciding to stop operating the first and second decoders if the Hamming distance is less than a predetermined threshold value.

6. The method of claim 4, further comprising:
prior to deciding whether to stop operating the first and second decoders, setting the threshold value equal to a value based on an earlier-determined Hamming distance,
wherein deciding whether to stop operating the first and second decoders based on a comparison of the Hamming distance with the threshold value comprises deciding to stop operating the first and second decoders if the Hamming distance is greater than the threshold value.

7. The method of claim 6, wherein the earlier-determined Hamming distance is determined from an earlier-generated output from the first decoder and an earlier-generated output from the second decoder, the earlier-generated outputs from the first and second decoders being generated during an immediately preceding half-iteration.

8. The method of claim 1, wherein comparing the output from the first decoder with the output from the second decoder comprises:
comparing soft values from the first decoder with soft values from the second decoder.

9. The method of claim 8, wherein comparing soft values from the first decoder with soft values from the second decoder comprises:
determining a distance between soft values from first decoder and soft values from second decoder.

10. The method of claim 9, wherein deciding whether to stop operating the first and second decoders by comparing the output from the first decoder with the output from the second decoder comprises:
deciding to stop operating the first and second decoders based on a comparison of the distance with a threshold value.

11. The method of claim 10, wherein deciding to stop operating the first and second decoders comprises:
deciding to stop operating the first and second decoders if the distance is less than a predetermined threshold value.

12. The method of claim 10, further comprising:
prior to deciding whether to stop operating the first and second decoders, setting the threshold value equal to a value based on an earlier-determined distance,
wherein deciding whether to stop operating the first and second decoders based on a comparison of the distance with the threshold value comprises deciding to stop operating the first and second decoders if the distance is greater than the threshold value.

13. The method of claim 12, wherein the earlier-determined distance is determined from an earlier-generated output from the first decoder and an earlier-generated output from the second decoder, the earlier-generated outputs from the first and second decoders being generated during an immediately preceding half-iteration.

14. The method of claim 1, further comprising:
prior to the one or more of the m half-iterations, operating the first and second decoders in parallel for an initial number of half-iterations without deciding whether to stop operating the first and second decoders.

15. The method of claim 1, wherein each of the first and second decoders is a maximum a posteriori (MAP) decoder, and wherein comparing the output from the first decoder with the output from the second decoder comprises:
comparing an intermediate result from the first decoder with an intermediate result from the second decoder.

16. A method of decoding Turbo encoded information that comprises first systematic bits, first parity bits, second systematic bits, and second parity bits, the method comprising:
supplying the first systematic bits and the first parity bits to a first decoder;
supplying the second systematic bits and the second parity bits to a second decoder;
operating the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
after one or more of the m half-iterations, deciding whether to stop operating the first and second decoders based on a comparison of an output from the first decoder with an output from the second decoder and on an assessment of a reliability of decisions supplied at outputs of the first and second decoders.

17. The method of claim 16, wherein the assessment of the reliability of decisions supplied at outputs of the first and second decoders is performed in accordance with
$$γ \begin{matrix}{<}^{OK} \\ {>}_{not OK}\end{matrix} min ( {\sum }_{k}^{} \vert {S}_{1 , k} \vert , {\sum }_{k}^{} \vert {S}_{2 , k}^{i} \vert ) ,$$
where γ is a threshold value, S₁ is a soft output of the first decoder, Sⁱ₂ is a de-interleaved soft output of the second decoder, and S_{1,k} and Sⁱ_{2,k} are the k:th components of S₁ and Sⁱ₂, respectively.

18. An apparatus for decoding Turbo encoded information that comprises first systematic bits, first parity bits, second systematic bits, and second parity bits, the apparatus comprising:
logic that supplies the first systematic bits and the first parity bits to a first decoder;
logic that supplies the second systematic bits and the second parity bits to a second decoder;
logic that operates the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
logic that decides, after one or more of the m half-iterations, whether to stop operating the first and second decoders by comparing an output from the first decoder with an output from the second decoder.

19. The apparatus of claim 18, wherein comparing the output from the first decoder with the output from the second decoder comprises:
comparing a hard decision from the first decoder with a hard decision from the second decoder.

20. The apparatus of claim 19, wherein the logic that decides whether to stop operating the first and second decoders by comparing the output from the first decoder with the output from the second decoder comprises:
logic that decides to stop operating the first and second decoders if the hard decision from the first decoder is equal to the hard decision from the second decoder.

21. The apparatus of claim 19, wherein the logic that decides whether to stop operating the first and second decoders by comparing the output from the first decoder with the output from the second decoder comprises:
logic that determines a Hamming distance between the output from the first decoder and the output from the second decoder; and
logic that decides whether to stop operating the first and second decoders based on a comparison of the Hamming distance with a threshold value.

22. The method of claim 21, wherein the logic that decides whether to stop operating the first and second decoders comprises:
logic that decides to stop operating the first and second decoders if the Hamming distance is less than a predetermined threshold value.

23. The apparatus of claim 21, further comprising:
logic that sets the threshold value equal to a value based on an earlier-determined Hamming distance prior to deciding whether to stop operating the first and second decoders,
wherein the logic that decides whether to stop operating the first and second decoders based on a comparison of the Hamming distance with the threshold value comprises logic that decides to stop operating the first and second decoders if the Hamming distance is greater than the threshold value.

24. The apparatus of claim 23, wherein the earlier-determined Hamming distance is determined from an earlier-generated output from the first decoder and an earlier-generated output from the second decoder, the earlier-generated outputs from the first and second decoders being generated during an immediately preceding half-iteration.

25. The apparatus of claim 18, wherein comparing the output from the first decoder with the output from the second decoder comprises:
comparing soft values from the first decoder with soft values from the second decoder.

26. The apparatus of claim 25, wherein comparing soft values from the first decoder with soft values from the second decoder comprises:
determining a distance between soft values from first decoder and soft values from second decoder.

27. The apparatus of claim 26, wherein the logic that decides whether to stop operating the first and second decoders by comparing the output from the first decoder with the output from the second decoder comprises:
logic that decides to stop operating the first and second decoders based on a comparison of the distance with a threshold value.

28. The apparatus of claim 27, wherein the logic that decides to stop operating the first and second decoders comprises:
logic that decides to stop operating the first and second decoders if the distance is less than a predetermined threshold value.

29. The apparatus of claim 27, further comprising:
logic that sets the threshold value equal to a value based on an earlier-determined distance prior to deciding whether to stop operating the first and second decoders,
wherein the logic that decides whether to stop operating the first and second decoders based on a comparison of the distance with the threshold value comprises logic that decides to stop operating the first and second decoders if the distance is greater than the threshold value.

30. The apparatus of claim 29, wherein the earlier-determined distance is determined from an earlier-generated output from the first decoder and an earlier-generated output from the second decoder, the earlier-generated outputs from the first and second decoders being generated during an immediately preceding half-iteration.

31. The apparatus of claim 18, further comprising:
logic that, prior to the one or more of the m half-iterations, operates the first and second decoders in parallel for an initial number of half-iterations without deciding whether to stop operating the first and second decoders.

32. The apparatus of claim 18, wherein each of the first and second decoders is a maximum a posteriori (MAP) decoder, and wherein comparing the output from the first decoder with the output from the second decoder comprises:
comparing an intermediate result from the first decoder with an intermediate result from the second decoder.

33. An apparatus for decoding Turbo encoded information that comprises first systematic bits, first parity bits, second systematic bits, and second parity bits, the apparatus comprising:
logic that supplies the first systematic bits and the first parity bits to a first decoder;
logic that supplies the second systematic bits and the second parity bits to a second decoder;
logic that operates the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
logic that, after one or more of the m half-iterations, decides whether to stop operating the first and second decoders based on a comparison of an output from the first decoder with an output from the second decoder and on an assessment of a reliability of decisions supplied at outputs of the first and second decoders.

34. The apparatus of claim 33, wherein the assessment of the reliability of decisions supplied at outputs of the first and second decoders is performed in accordance with
$$γ \begin{matrix}{<}^{OK} \\ {>}_{not OK}\end{matrix} min ( {\sum }_{k}^{} \vert {S}_{1 , k} \vert , {\sum }_{k}^{} \vert {S}_{2 , k}^{i} \vert ) ,$$
where γ is a threshold value, S₁ is a soft output of the first decoder, Sⁱ₂ is a de-interleaved soft output of the second decoder, and S_{1,k} and Sⁱ_{2,k} are the k:th components of S₁ and Sⁱ₂, respectively.

35. A computer-readable medium having stored thereon a computer program for decoding Turbo encoded information that comprises first systematic bits, first parity bits, second systematic bits, and second parity bits, the computer program comprising instructions for performing:
supplying the first systematic bits and the first parity bits to a first decoder;
supplying the second systematic bits and the second parity bits to a second decoder;
operating the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
after one or more of the m half-iterations, deciding whether to stop operating the first and second decoders by comparing an output from the first decoder with an output from the second decoder.

36. A computer readable medium having stored thereon a computer program for decoding Turbo encoded information that comprises first systematic bits, first parity bits, second systematic bits, and second parity bits, the computer program comprising instructions for performing:
supplying the first systematic bits and the first parity bits to a first decoder;
supplying the second systematic bits and the second parity bits to a second decoder;
operating the first and second decoders in parallel for a number, m, of half-iterations, wherein m is greater than or equal to 1, wherein for each of the m half-iterations, the first decoder utilizes soft information supplied as an output from the second decoder in a preceding half-iteration, and the second decoder utilizes soft information supplied as an output from the first decoder in the preceding half-iteration;
after one or more of the m half-iterations, deciding whether to stop operating the first and second decoders based on a comparison of an output from the first decoder with an output from the second decoder and on an assessment of a reliability of decisions supplied at outputs of the first and second decoders.
